(19) United States
(12) Patent Application Publication
(10) Pub. No.: US 2025/0124179 A1
(43) Pub. Date: Apr. 17, 2025

(54) METHODS AND SYSTEMS FOR RAPID DESIGN AND DELIVERY OF SPACECRAFTS

(71) Applicant: Proteus Space, Inc., Los Angeles, CA (US)

(72) Inventors: Eleftherios Gdoutos, Los Angeles, CA (US); Andrew A. Shapiro, Los Angeles, CA (US); David Kervin, Los Angeles, CA (US)

(21) Appl. No.: 18/760,561

(22) Filed: Jul. 1, 2024

Related U.S. Application Data
(60) Provisional application No. 63/589,586, filed on Oct. 11, 2023.

(51) Int. Cl. G06F 30/15; G06F 30/23

(52) U.S. Cl. CPC G06F 30/15; G06F 30/23

(57) ABSTRACT

A method for automated spacecraft design includes receiving mission parameters provided by a client for spacecraft design, generating one or more concept designs based on the received mission parameters, each concept design including one or more components selected for each subsystem included in a designed spacecraft, for each concept design, generating a CAD model including a collection of CADs representing structures of the one or more components selected for each subsystem included in the designed spacecraft, performing a series of analyses or simulations to evaluate a performance of the CAD model, and generating a digital twin representing a virtual representation of the designed spacecraft.

### CROSS-REFERENCE TO RELATED APPLICATION

This application claims the benefit of and priority to the U.S. Provisional Patent Application No. 63/589,586, filed on Oct. 11, 2023, and titled “METHODS AND SYSTEMS FOR RAPID DESIGN AND DELIVERY OF SATELLITES,” the entire content of which is incorporated herein by reference in its entirety.

### TECHNICAL FIELD

The present disclosure relates generally to the design and delivery of spacecrafts, and more specifically, to software-based methods and systems for rapid design and delivery of spacecrafts.

### BACKGROUND

State-of-the-art processes for designing and delivering spacecrafts are lengthy, cumbersome, and expensive. For example, design and delivery of an evolved expendable launch vehicle (EELV) secondary payload adapter (ESPA)-class spacecraft generally takes between 28 and 48 months (including 14-30 months for mission formulation and spacecraft design), and requires substantial time and input from subject-matter experts. Techniques for more rapid and less expensive design and delivery of spacecrafts are needed.

The foregoing examples of the related art and limitations therewith are intended to be illustrative and not exclusive, and are not admitted to be “prior art.” Other limitations of the related art will become apparent to those of skill in the art upon a reading of the specification and a study of the drawings.

### SUMMARY

According to some embodiments, the present disclosure provides a method for automated spacecraft design. The method includes receiving mission parameters provided by a client for spacecraft design, generating one or more concept designs based on the received mission parameters, each concept design including one or more components selected for each subsystem included in a designed spacecraft, for each concept design, generating a computer aided design (CAD) model including a collection of CADs representing structures of the one or more components selected for each subsystem included in the designed spacecraft, performing a series of analyses or simulations to evaluate a performance of the CAD model, and generating a digital twin representing a virtual representation of the designed spacecraft.

The foregoing is a summary and thus contains, by necessity, simplifications, generalizations and omissions of detail; consequently, the summary is illustrative only and is not limiting in any way. Other aspects, inventive features, and advantages of the systems and/or processes described herein will become apparent in the non-limiting detailed description set forth herein.

### BRIEF DESCRIPTION OF THE DRAWINGS

The accompanying figures, which are included as part of the present specification, illustrate the presently preferred embodiments and together with the general description given above and the detailed description of the preferred embodiments given below serve to explain and teach the principles described herein.

FIG. 1 is a flowchart of a process for designing and delivering a spacecraft, in accordance with some embodiments.

FIG. 2A is a flowchart of a conceptual design method of a spacecraft design process, in accordance with some embodiments.

FIG. 2B is an illustration of input/output of a conceptual design method of a spacecraft design process, according to an example.

FIG. 3A is a flowchart of a preliminary design method of a spacecraft design process, in accordance with some embodiments.

FIG. 3B is an illustration of input/output of a preliminary design method of a spacecraft design process, according to an example.

FIG. 3C illustrates example outputs at different stages of a spacecraft design process, according to one example.

FIG. 4 illustrates a process flow of a conceptual design method of a spacecraft design process, in accordance with some embodiments.

FIGS. 5A-5D illustrate various subsystem selections in a spacecraft design process, in accordance with some embodiments.

FIG. 6 illustrates a system architecture for automated spacecraft design, in accordance with some embodiments.

FIG. 7 illustrates an example outcome of a generative spacecraft design for additive manufacturing, in accordance with some embodiments.

FIG. 8 is a block diagram of an example computer system, in accordance with some embodiments.

It will be appreciated that, for simplicity and clarity of illustration, where considered appropriate, reference numerals may be repeated among the figures to indicate corresponding or analogous elements.

### DETAILED DESCRIPTION

The present disclosure describes software-based methods and systems for rapid design and delivery of spacecrafts (such as space vehicles and satellites among others). The Figures (FIGS.) and the following description relate to preferred embodiments by way of illustration only. It should be noted that from the following discussion, alternative embodiments of the structures and methods disclosed herein will be readily recognized as viable alternatives that may be employed without departing from the principles of the disclosure.

### A Process for Designing and Delivering a Spacecraft

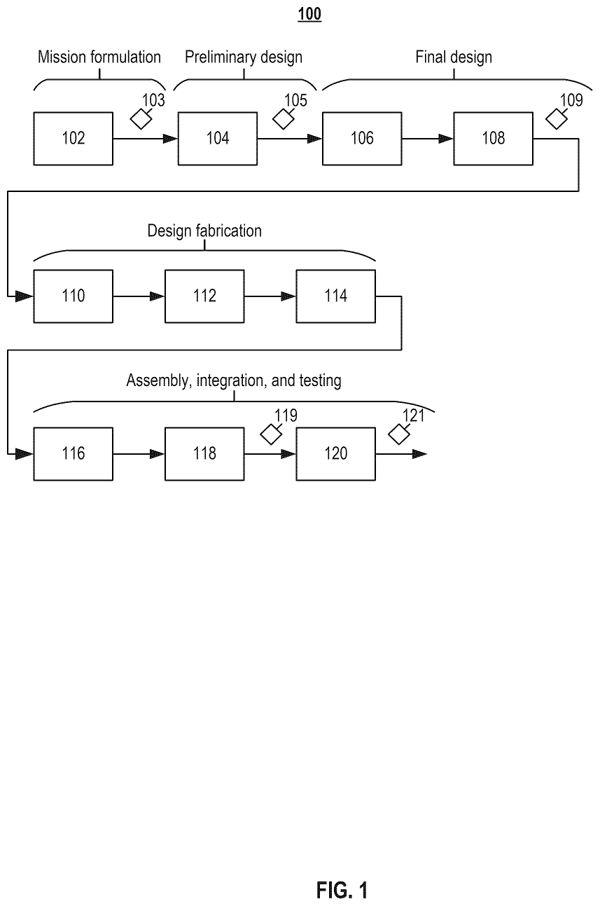

FIG. 1 illustrates a process 100 for designing and delivering a spacecraft. In the example of FIG. 1, the design and delivery process includes four phases. Phase A (mission formulation) includes steps 102-103. Phase B (preliminary design) includes steps 104-105. Phase C (final design and design fabrication) includes steps 106-114. Phase D (assembly, integration, and testing) includes steps 116-121. It should be noted that these phases are traditionally defined by the NASA systems engineering handbook. Because the execution of the system disclosed herein is automated, the outlined steps may roughly correspond to the NASA guidelines.

Phase A (mission formulation) includes steps 102-103. In existing implementations, Phase A generally takes between 3 and 6 months.

In step 102, the spacecraft's mission is formulated. Mission formulation may involve defining the mission (often with input from the entity that will own or operate the spacecraft) and determining system requirements for the spacecraft based on the mission. In existing implementations of the process 100, step 102 is generally a manual, iterative process developed in the 20th century that is prone to scope creep with little to no digitization of requirements. In addition, at step 102, large part counts introduce substantial room for error and increased complexity in supply chain tracking, inspection, and assembly.

In step 103, a system requirements review (SRR) is conducted. The SRR examines the functional and performance requirements defined for the system to determine whether the requirements satisfy the mission.

Phase B (preliminary design) includes steps 104-105. In existing implementations, Phase B generally takes between 3 and 8 months.

In step 104, a preliminary design for the spacecraft is generated. The preliminary design step may involve using systems engineering techniques to develop a block diagram of the spacecraft system. Existing implementations of step 104 tend to be highly bespoke, such that the preliminary design is generated from scratch according to the unique requirements of the mission. In existing implementations, the highly customized nature of the preliminary design step tends to be incompatible with modern, rapidly advanced manufacturing processes. Likewise, the highly customized approach to preliminary design tends to produce parts and subsystems with highly complex geometries that require significant design time to be manufacturable. Furthermore, in existing implementations, the structural and thermal design components of the preliminary design step tend to be manual processes reliant on individual know-how and often require subject matter experts (SMEs).

In step 105, a preliminary design review (PDR) is conducted. The purposes of the PDR may include (1) determining whether the preliminary design meets all system requirements with acceptable risk and within the cost and schedule constraints and (2) establishing the basis for proceeding with the final design.

Phase C includes two sub-phases, final design (steps 106-109) and design fabrication (steps 110-114). In existing implementations, the final design sub-phase generally takes between 8 and 16 months, and the design fabrication sub-phase generally takes between 8 and 10 months.

In step 106, subsystems of the spacecraft are procured. In step 108, spacecraft design and analysis are performed. In step 109, a critical design review (CDR) is conducted. The purposes of the CDR may include (1) determining whether the final design meets all mission performance requirements within the identified cost and schedule constraints, and (2) establishing the basis for proceeding with full-scale design fabrication, assembly, integration, and testing.

In step 110, a flat spacecraft (FlatSat) is assembled. The FlatSat may include a motherboard where spacecraft avionics modules can be installed and connected as if inside the actual spacecraft structure, and may function as a ground-based testbed for the spacecraft (e.g., for CubeSat testing). In step 112, functional testing and software testing may be conducted. In step 114, the SV structure may be fabricated.

In existing implementations of Phase C, numerous practices give rise to substantial delay. For example, legacy computer numerical control (CNC)—based processes can impose time-consuming and capability-limiting constraints on the design. So-called “standard buses” may require time-consuming modifications or may not be compatible with the mission requirements. A non-optimal theory of forcing new, sometimes revolutionary capabilities to fit standardized designs can impose additional capability-limiting constraints. The absence of systematic operations process flow can cause additional delays.

Phase D (assembly, integration, and testing) includes steps 116-121. In existing implementations, Phase D generally takes between 6 and 8 months.

In step 116, the spacecraft subsystems and structure are assembled. In step 118, system functional testing is conducted. In step 119, a test readiness review (TRR) is conducted. The purposes of the TRR may include determining whether the test system (hardware and software), test facility, support personnel, and test procedures are ready for environmental. In step 120, environmental testing is conducted. In step 121, a program status review (PSR) is conducted.

In existing implementations of Phase D, numerous practices give rise to additional delay. For example, if there has been inadequate or minimal unit-level testing in the earlier Phases, the systems-level testing in Phase D may reveal many unit-level errors at a mature level of integration, resulting in significant delays. In addition, the testing process may require significant oversight by subject matter experts, because the testing protocols may not be rigorously defined and/or may involve only minimal automation.

### Motivation for and Benefits of Some Embodiments

In existing implementations, the process 100 for designing and delivering a spacecraft (e.g., an ESPA-class or smaller spacecraft), including Phases A-D, generally takes between 28 and 48 months. Phases A, B, and the final design sub-phase of Phase C generally take between 14 and 30 months. Techniques for more rapid and less expensive design and delivery of spacecrafts are needed.

The present disclosure describes software-based methods and systems for rapid and inexpensive design and delivery of spacecrafts. In some cases, computer systems and/or software configured to perform the methods described herein may be referred to as “Spec to Spacecraft” (STS) systems (which may have a name of “MERCURY” system or another different name) and/or software. An STS system may include a mechanical engineering module (e.g., software module) configured to perform mechanical engineering tasks, an orbital modeling module (e.g., software module) configured to perform orbital modeling tasks, a systems engineering module (e.g., software module) configured to perform systems engineering tasks, etc. In some embodiments, the STS software modules described herein can reduce the time spent in the spacecraft formulation and design phases of an ESPA-class spacecraft (i.e., Phases A, B, and the final design sub-phase of Phase C) from 14-30 months to 2 months. In some embodiments, the STS software modules described herein leverage commercial off-the-shelf (COTS) spacecraft subsystem capabilities and enable automated real-time spacecraft systems and computer aided design based on an input of mission requirements.

In some embodiments, the methods and systems described herein provide an automated design and production process for rapid, modular, technology-refreshable spacecrafts at scale, yielding a spacecraft design process that is fast, relatively inexpensive, modern, and scalable.

In some embodiments, the methods and systems described herein provide a computer model for mission formulation and a computer model of a spacecraft design. The computer model of a spacecraft design may be referred to herein as a “spacecraft digital twin (or simply ‘digital twin’),” which is a collection of models that represent various aspects (e.g., physical or operation states) of a spacecraft where the digital twin is updated with the current state of a physical twin (also referred to as “hardware twin”), and the physical twin is informed, actuated or influenced by the digital twin. The updates can be performed manually or can be automated.

In some embodiments, the mission formulation model and the spacecraft digital twin together may enable near real-time tradespace comparison (e.g., analysis of the tradeoffs among resources, costs, and provisioning for different spacecraft designs in the design space). In some embodiments, the mission formulation model provides a digitized, reviewable, and traceable definition of the mission requirements. In some embodiments, the spacecraft digital twin seamlessly interfaces with mission analysis and test models for on-ground operations validation.

In some embodiments, the methods and systems described herein provide automation of the spacecraft system design process based on digitized mission requirements. System designs may be performance-index optimized, such that the STS software can generate different designs depending on the prioritization or ranking of performance metrics. For example, the STS software can optimize the spacecraft design for a given set of mission requirements to minimize cost if cost is the primary performance metric, or optimize the design for the same set of mission requirements to minimize lead time if lead time is the primary performance metric. Budgets for resources (e.g., mass, power, data, etc.) may be automatically generated and digitally linked to mission requirements. In some embodiments, automated, traceable, and codified rules-based design evolutions may be provided. For example, the STS software may automatically evolve the design of a given spacecraft to accommodate new, slightly different mission parameters (e.g., a new, slightly different payload) with minimal user input. When the STS software engages in automated design evolution, the software may document the changes in the spacecraft design and the reasons for those changes, so that the changes are visible and directly traceable to the corresponding changes in mission requirements. Such design evolutions may be codified and rule-based in the sense that the changes in spacecraft design are derived from software-based rules (e.g., parametric equations) that relate mission requirements to design specifications.

In some embodiments, the methods and systems described herein may incorporate design for manufacturing and assembly (DFMA) methodologies (e.g., best practices) and/or design for additive manufacturing (DFAM) methodologies. DFMA refers to the combination of two design methodologies: design for manufacture (e.g., design for ease of manufacture of the parts that will form a product) and design for assembly (e.g., design of the product for ease of assembly). DFMA may be used as the basis for concurrent engineering studies to provide guidance to the design team in simplifying the spacecraft system, reducing manufacturing and assembly costs, and quantifying improvements. DFAM refers to design for manufacturability as applied to additive manufacturing (AM), such that functional performance and/or other system life-cycle considerations (e.g., manufacturability, reliability, cost, etc.) are optimized subject to the capabilities of additive manufacturing technologies.

In some embodiments, DFMA and DFAM methodologies for design and/or delivery of spacecrafts may include automatically determining harness length and path, providing a line of sight to fasteners, and/or providing connector clearances. The combination of modularity, low parts-count, and automated DFMA may enable production and assembly at scale, yielding modular and refreshable spacecraft designs. Also, NASA/JPL have shown that additive manufacturing techniques can enable faster design refresh and added capabilities in the frame/bus. Additive manufacturing techniques may also yield refreshed payload accommodation with minimal changes to the production, assembly, and test processes. In some embodiments, additive manufacturing techniques enable integration of function in the spacecraft frame (e.g., harnessing channels or heat pipes), thereby providing greater spacecraft capability without increasing assembly complexity. By automatically incorporating DFMA and/or DFAM methodologies into the spacecraft design process, the STS software may enable significant reductions in the duration and expense of spacecraft design and delivery. Furthermore, the STS software's benefits may increase over time, as the software accumulates libraries of previous designs and learns from previous iterations of the design process.

In some embodiments, the methods and systems described herein incorporate automated process flow and agile-based testing. For example, the methods and systems described herein may include unit-level testing early in the spacecraft manufacturing process, thereby reducing propagation of errors to higher levels of integration which often require more time to troubleshoot. Codified test specifications and sequences derived from mission requirements may be incorporated into the assembly process flow.

In some embodiments, the methods and systems described herein provide (1) automated estimates of the cost or price of designing and delivering a spacecraft system, (2) automated scheduling of spacecraft assembly, integration, and test activities, and/or (3) identification of longest lead time component.

### Some Embodiments of Spacecrafts

The term “spacecraft” can refer to any object configured to orbit a celestial body. Spacecrafts can have a variety of uses, including communication relay, weather forecasting, navigation (e.g., GPS), broadcasting, scientific research, and/or Earth observation. Additional military uses may include reconnaissance, early warning, signals intelligence and weapon delivery. Example spacecrafts include but are not limited to various satellites, space vehicles, etc.

Most spacecrafts are composed of certain subsystems, for example, communications subsystem, payload subsystem, power subsystem, propulsion subsystem, attitude determination and control system (ADCS) & guidance, navigation and control (GN&C) subsystem, command and data handling (CDH) subsystem. For example, most spacecrafts have an electricity generation system (e.g., solar panels or radioisotope thermoelectric generators (RTGs)) to provide power to on-board equipment. Most spacecrafts have communication equipment (e.g., transponders) suitable for communication with ground stations. Many communication spacecrafts are radio relay stations carrying dozens of transponders, each with a bandwidth of tens of megahertz.

Some subsystems are made of assemblies, where each assembly includes a certain number of components organized in a specific manner. For example, a power assembly may include one or more photovoltaic (PV) cells, one or more batteries, and one or more power distribution units (PDUs), and a CDH assembly may include one or more on-board computers (OBCs) and one or more storage components. Under certain circumstances, these assemblies are prebuilt by providers with components provided as a single piece of equipment.

Many spacecrafts use a standardized bus (e.g., CubeSats). Similar spacecrafts can work together as groups, forming constellations. Because of the high launch cost to space, spacecrafts are generally designed to be as lightweight and robust as possible.

Orbital launch vehicles carry spacecrafts into space and place them in orbit high enough to avoid orbital decay by the atmosphere. Spacecrafts can then change or maintain the orbit by propulsion, usually by chemical or ion thrusters. Most of the spacecrafts orbiting the Earth are in low Earth orbit or geostationary orbit. Some imaging spacecrafts have a Sun-synchronous orbit so they can scan the entire globe with similar lighting. Most spacecrafts use chemical or ion propulsion to adjust or maintain their orbit, coupled with reaction wheels to control their three axes of rotation or attitude. Without orbit and orientation control, spacecrafts in orbit are generally unable to communicate with ground stations on the Earth.

ESPA-class spacecrafts are carried by a specific adapter used for launching secondary payloads on orbital launch vehicles. The adapter may be an ESPA adapter, sometimes referred to as an “ESPA ring.” The ESPA utilizes excess launch capacity on an orbital launch vehicle by mounting one or more additional payloads (e.g., ESPA-class spacecrafts) below the primary spacecraft. The use of ESPA-class spacecrafts reduces launch costs for the primary mission and enables secondary and even tertiary spacecrafts with minimal impact on the original mission.

### Some Embodiments of Improved Methods for Spacecraft Design

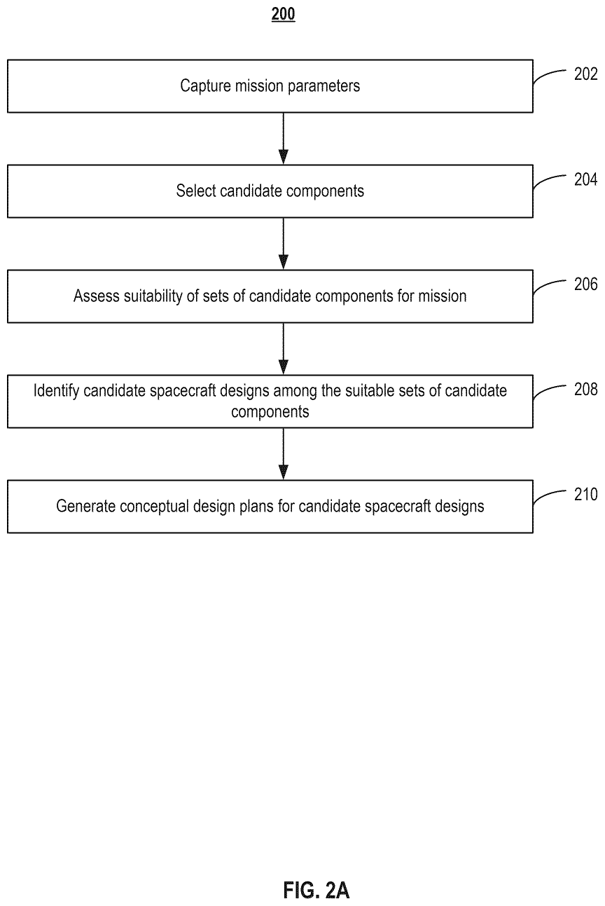

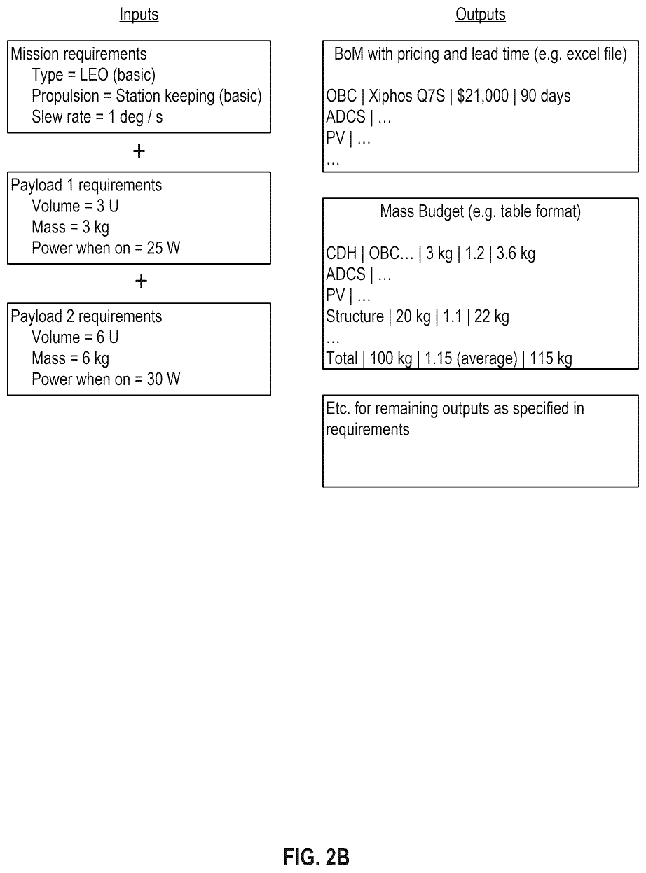

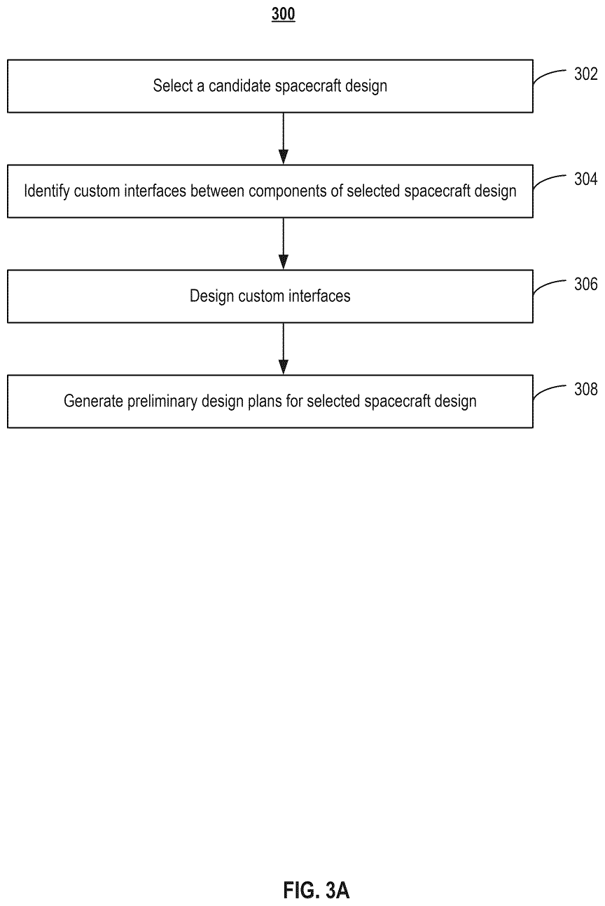

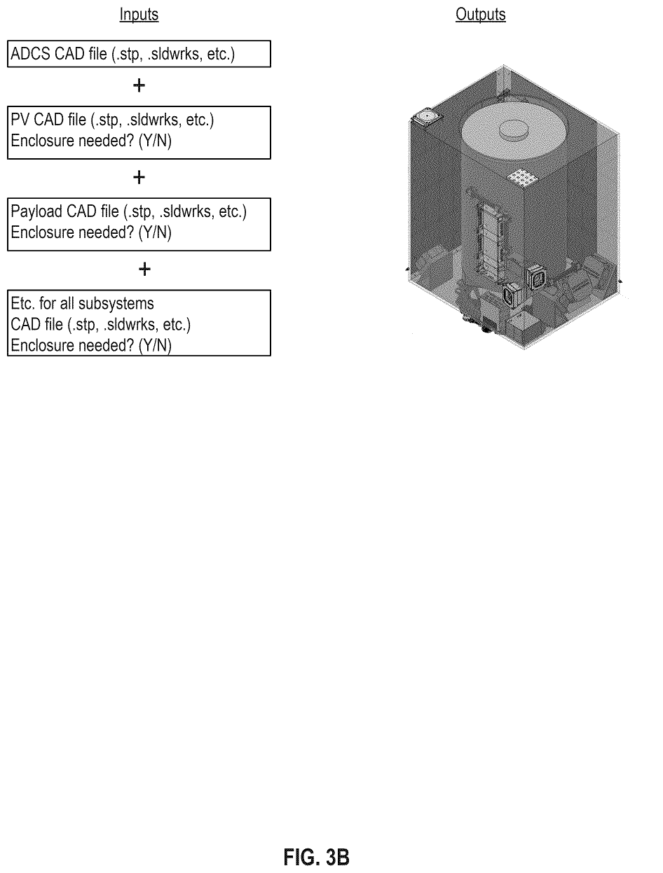

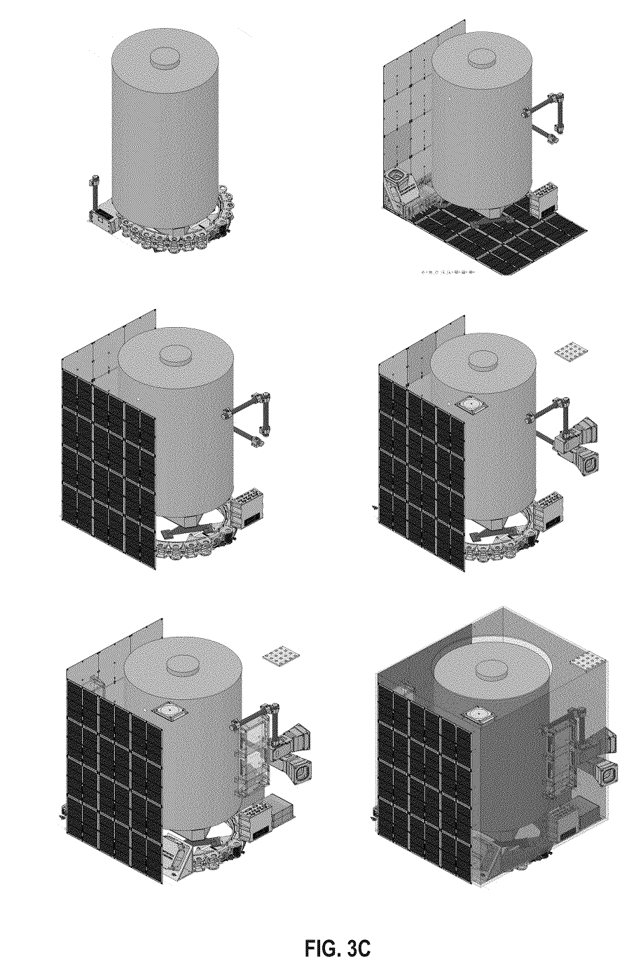

FIG. 2A shows a conceptual design method 200 of a spacecraft design process, according to some embodiments. In some embodiments, the conceptual design method 200 may be used to perform steps 102-103 of the process 100 for designing and delivering a spacecraft. In some embodiments, an STS system performing the conceptual design method 200 may receive as input data indicating the mission parameters for a spacecraft, and may provide as output conceptual designs for one or more spacecrafts that satisfy the mission parameters. FIG. 3A shows a preliminary design method 300 of a spacecraft design process. In some embodiments, the preliminary design method 300 may be used to perform steps 104-105 of the process 100 for designing and delivering a spacecraft. In some embodiments, an STS system performing the preliminary design method 300 may receive as input conceptual designs for a spacecraft, and may provide as output preliminary designs for the spacecraft. The conceptual design method 200 and the preliminary design method 300 may be performed by an STS system, which may perform some or all of the tasks generally performed during steps 102-105 of existing implementations of the process 100 (e.g., by systems engineers and/or mechanical engineers).

In existing implementations of steps 102-103 of the process 100, a systems engineer may spend 2-6 weeks sorting through capabilities (COTS subsystems) and/or writing requirements for the subsystems. The systems engineer generally iterates on this task at least twice for a minimum total of 4-12 weeks of preliminary subsystem selection. The systems engineer may then spend about 2-4 weeks synthesizing mass tables, power tables, block diagrams, and bills of materials.

Referring to FIG. 2A, a conceptual design method 200 of a spacecraft design process may include steps 202-210. In step 202, the STS system captures one or more mission parameters (or “mission requirements”). In some embodiments, the STS system captures the mission parameters by obtaining (e.g., receiving as input) data indicating a set of spacecraft mission parameters. In some embodiments, the mission parameters are user-specified. In some embodiments, the values of the mission parameters are specified in an input file stemming from a mission design digital twin. In some embodiments, the number of specified mission parameters may be between 3 and 20. Some non-limiting examples of mission parameters may include power, size, mass, communications, pointing, etc.

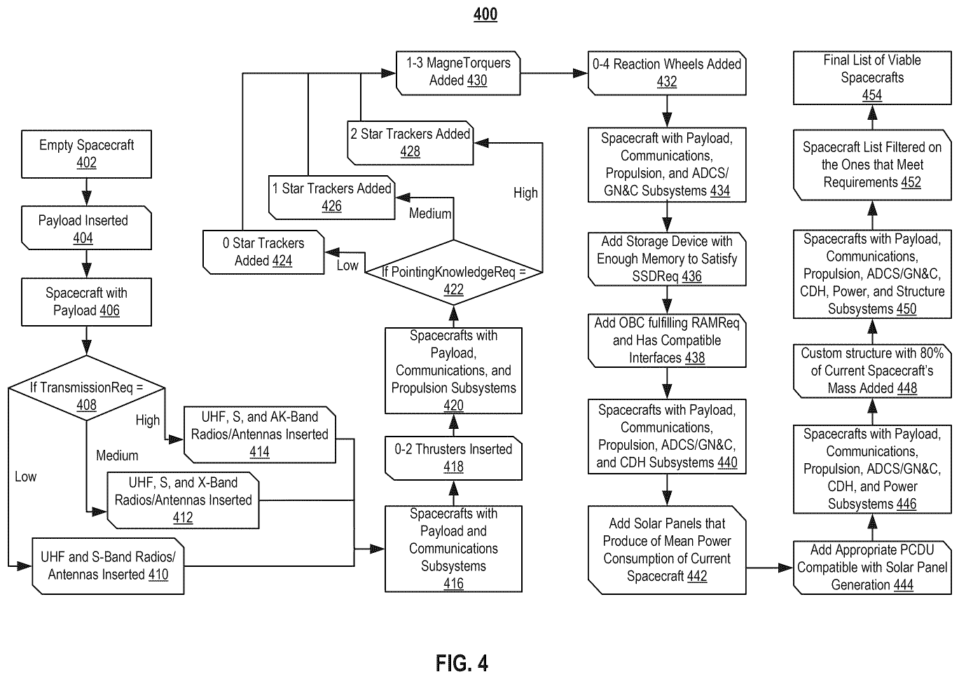

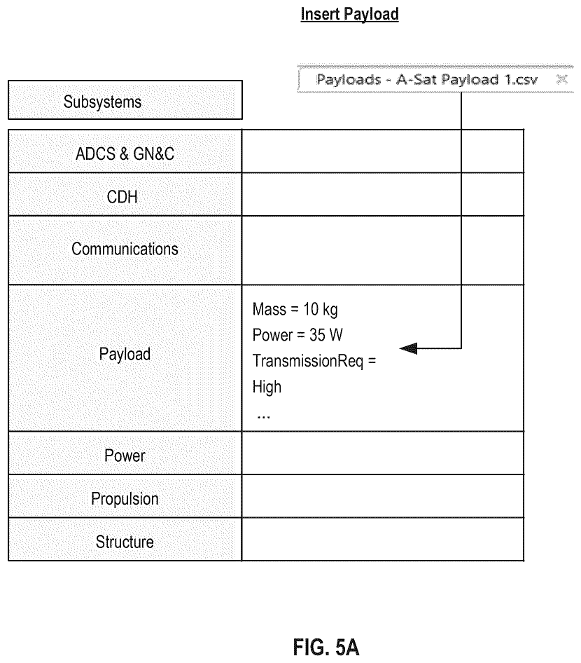

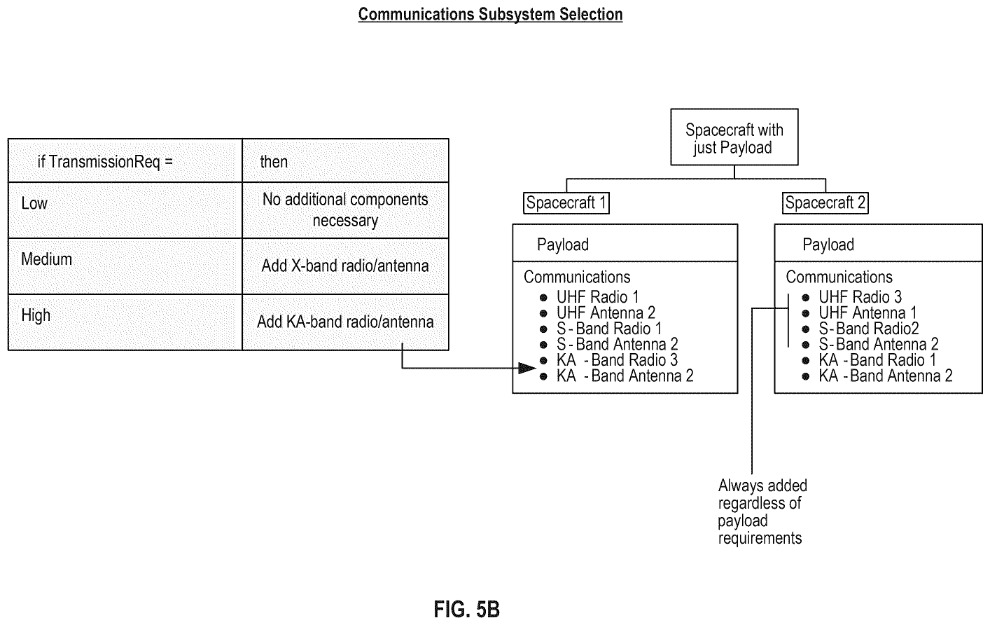

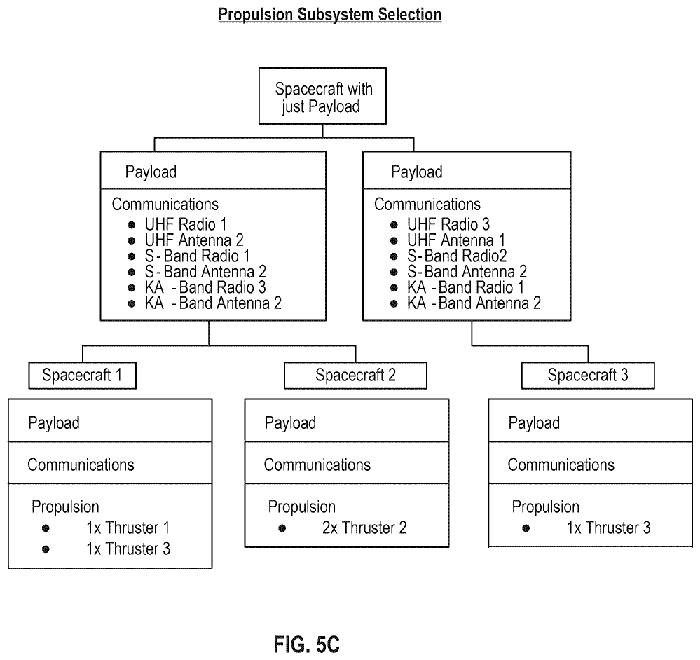

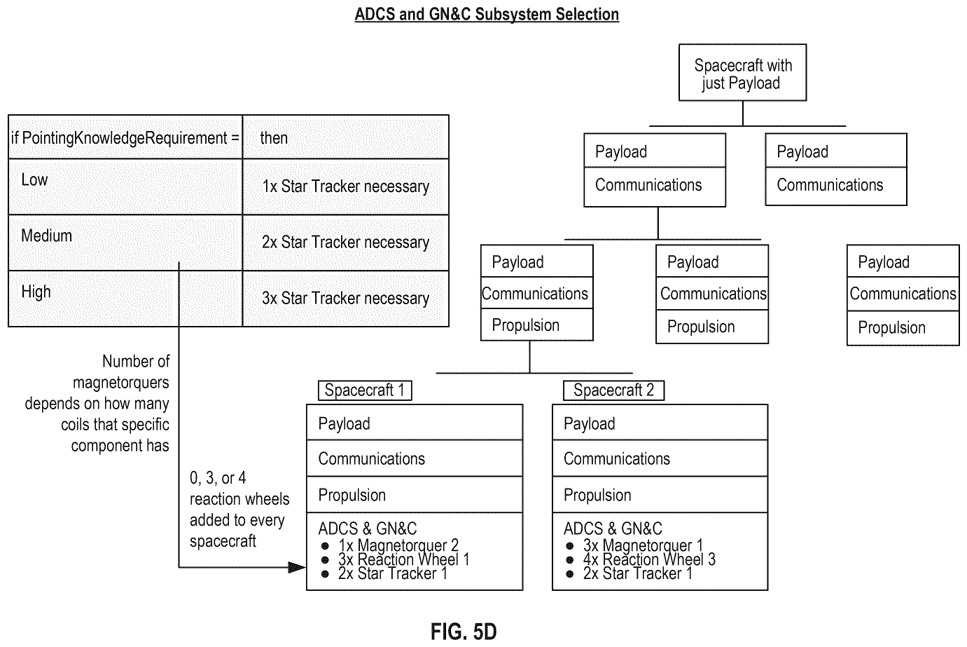

In step 204, the STS system selects candidate components for the spacecraft. The candidate components may include candidate subsystems, modules, parts, etc. In some embodiments, the candidate components are selected by a systems engineering module (“SE module”). In some embodiments, the SE module may provide two or more (e.g., 2-4) candidates for each component (including component specifications) at step 204. In some embodiments of step 204, the SE module selects candidate components automatically based on the mission parameters. The specific process of selecting components for different subsystems is further described in detail in FIGS. 4-5D.

In some embodiments, the SE module includes a data table of spacecraft components and specification parameters (e.g., lead time, price, etc.). In some embodiments, the SE module includes a data set of specification parameters for each component. In some embodiments, the data set of specification parameters for each component (1) enables mapping of components to mission parameters, (2) enables block diagram generation, (3) enables materials equipment list (MEL) generation, (4) enables power equipment list (PEL) generation, and/or (5) includes volume information, part number information, lead time information, and/or cost information. In some embodiments, the data table of spacecraft components and their specification parameters are updatable on a periodic (e.g., daily, weekly, monthly) basis or as new data becomes available.

In some embodiments, the SE module includes data codifying relationships between component specification parameters and mission parameters. In some embodiments, the data-codified relationships between component specification parameters and mission parameters enable (1) identification of a set of components that meet mission parameters and (2) identification of a set of components with which mission parameters cannot be achieved. In some embodiments, data codified relationships between specification parameters for different components are provided. In some embodiments, the data codified relationships between specification parameters for different components enable (1) identification of a set of compatible components and (2) identification of specific incompatibilities between components.

In step 206, the STS system assesses the suitability of one or more sets (e.g., all possible sets) of the candidate components for the mission. As described above, some embodiments of the SE module can ascertain which sets of candidate components do or do not meet the mission parameters based on data codifying relationships between component specifications and mission parameters. In some embodiments of step 206, the SE module selects and keeps track of one or more sets (or combinations) of candidate components that satisfy the specified mission parameters. In some embodiments, the SE module identifies (1) one or more complete sets of components that meet the mission parameters, and/or (2) one or more sets of components that meet the one or more mission parameters and fail to meet one or more other mission parameters. Each set of components that satisfies all the mission parameters may be referred to as a “candidate set of components” or “suitable set of components,” and each set of components that fails to satisfy one or more mission parameters may be referred to as an “unsuitable set of components.” For each unsuitable set of components, the SE module may identify which parameters are satisfied and which parameters are not satisfied by each set of components. In some embodiments, the SE module may identify a set of candidate components as a suitable set of components only if the components within the set have compatible interfaces or otherwise are compatible with each other.

In step 208, the STS system identifies one or more candidate spacecraft designs based on the suitable sets of components and on one or more performance metrics of interest. In some embodiments, the SE module analyzes the Pareto efficiency (or “Pareto optimality”) of the suitable sets of components with respect to two or more performance metrics (e.g., schedule, lead time, cost, power, mass, risk, margin of error with respect to mission parameters, etc.). In some embodiments, the SE modules identify any set of components that is on the Pareto frontier for at least two performance metrics of interest as a candidate spacecraft design. Other techniques for identifying one or more of the suitable sets of components as candidate spacecraft designs, or for assessing the optimality of the candidate spacecraft designs, are possible. In some embodiments, the SE module automatically selects sets of spacecraft components that satisfy the mission parameters and minimize (or maximize) performance metrics of interest.

In step 210, the STS system generates conceptual design plans for each of the candidate spacecraft designs. The conceptual design plan for a candidate spacecraft design may include, for example, a block diagram of the spacecraft design, an orbital model of the spacecraft design, data (e.g., a table) indicating the design's margins against the mission parameters, a computer-aided design (CAD) model of the spacecraft design, one or more resource budgets (e.g., mass budget, power budget, communication links budget, etc.) for the design, a bill of materials (BOM) for the design, cost or pricing data (e.g., a table) for the design, and/or lead-time data (e.g., a table) for the design. In some embodiments, the CAD model may be generated by a mechanical engineering (ME) module of the STS system. In some embodiments, the orbital model may be generated by an orbital modeling (OM) module of the STS system. In some embodiments, the block diagram, resource budgets, BoM, cost or pricing data, and lead-time data may be generated by the SE module.

Generation of the CAD model of the spacecraft design by the ME module may include one or more of the following steps. CAD files of the components of the spacecraft design may be imported. In some embodiments, the CAD files for all components are imported into a CAD assembly. In some embodiments, the ME module surveys and catalogs each of the spacecraft's components to determine whether it is in an enclosure. In some embodiments, the ME module identifies components not contained in enclosures (e.g., solar arrays, antennas, clamp-band, frame, harnessing, etc.). In some embodiments, the ME module groups components not in enclosures by subsystem. In some embodiments, the ME module automatically designs a rectangular/cubic stack-tray structural architecture for each subsystem group.

Generation of the CAD model of the spacecraft design by the ME module may further include one or more of the following steps. In some embodiments, the ME module arranges the enclosures. In some embodiments, the enclosures are arranged with minimum clearance between each pair of adjacent enclosures (e.g., 1 inch) into the smallest shape possible that most closely resembling a cube. In some embodiments, two or more alternative versions of the cube are provided. In some embodiments, the ME module adds solar arrays, antennas, and a separation system to the spacecraft design. If the solar arrays are deployable, they may be added to the two opposing faces of the cube. If the solar arrays are body-mounted, they may be added to one or more (e.g., all) otherwise uncovered faces of the cube. In some embodiments, the launch vehicle connecting clamp-band may be added to the face of the cube not covered by a solar array. In some embodiments, the CAD model produced by the ME module at step 210 visually resembles a spacecraft and is suitable for a rough, order-of-magnitude pricing proposal.

The conceptual design capabilities of the STS system may scale up over time. For example, the number of candidate components managed by the SE module may increase, which may lead to an increase in the number of sets of candidate components analyzed by the SE module for a mission. As another example, the SE module data codifying relationships between component specification parameters and mission parameters may be refined or enhanced over time, based on user feedback.

In some embodiments, the resource budgets in a conceptual design may include resource budgets for the mission as a whole and/or for different phases of the mission. In some embodiments, the block diagrams in a conceptual design may be detailed block diagrams (e.g., indicating voltage and data interfaces). In some embodiments, a bill of materials (BOM) in a conceptual design may have links to CAD models for the components in the BoM, and the CAD models may be suitable for handoff to a mechanical engineer. In some embodiments, a conceptual design may include metadata (e.g., metadata indicating whether each subsystem/component is provided in a structural enclosure by the supplier). In some embodiments, the conceptual design may be provided in a format suitable for use by a mechanical engineer and/or by government mission analysis and test digital twin software. In some embodiments, the SE module represents each conceptual design using a data structure suitable for representing spacecraft subsystems. Fields of the data structure may include technical specifications, price, lead time, etc.

In some embodiments, the STS system may perform the conceptual design method 200 in real-time. In some embodiments, prior to or while performing the conceptual design method 200, the STS system may allow the user to specify new components and update the data for components already managed by the SE module (e.g., specify new lead time, cost, or other information for a component).

In some embodiments, the SE module may accelerate conceptual spacecraft design by providing automated design and cost-estimation capabilities. In some embodiments, as part of step 202 of the conceptual design method 200, the SE module identifies gaps in the specified mission parameters. In some embodiments, the SE module prompts the user to provide inputs that fill the gaps in the specified mission parameters, yielding a complete set of mission parameters.

In some embodiments, the STS system generates conceptual spacecraft designs in a cloud-based computing environment (e.g., Azure or AWS).

In some embodiments, the CAD model produced at step 210 visually resembles a spacecraft and is suitable for a concept design review (CoDR). An example of an excerpt of a CoDR-level design is shown in FIG. 2B.

Referring to FIG. 3A, a preliminary design method 300 of a spacecraft design process may include steps 302-308. In some embodiments, the preliminary design method 300 may be used to perform steps 104-105 of the process 100 for designing and delivering a spacecraft. One or more steps of the preliminary design method 300 may be performed by a mechanical engineering module (ME module) of the STS system. In some embodiments, the ME module performs some or all of the tasks that a mechanical engineer generally performs during steps 104-105 of existing implementations of the process 100.

In existing implementations of steps 104-105 of the process 100, a mechanical engineer may spend 4 weeks procuring CAD files for the components of a conceptual spacecraft design and subsequently another 2-4 weeks arranging the parts and designing a frame to support them. Then, after review by a subject matter expert, the mechanical engineer may implement design rules, which generally involve iterating on arranging the components and designing the frame for another 2-4 weeks. The mechanical engineer may perform these tasks repeatedly depending on review findings.

In some embodiments, the STS system (e.g., ME module of the STS system) can automatically generate a preliminary spacecraft design based on a conceptual design (e.g., a conceptual design generated using the STS system's conceptual design method 200). In some embodiments, the ME module catalogs all subsystems available for use in the spacecraft design, imports CAD models of spacecraft components into the CAD environment, automatically designs enclosures for components (if required), generates a CAD-based model of the spacecraft frame (and, optionally, optimizes the design of the frame) and combines and arranges the CAD files to generate a preliminary spacecraft design (e.g., a CAD visualization of the spacecraft including spacecraft components, enclosures, and frame).

In step 302, a conceptual spacecraft design is selected. The spacecraft design may be selected from the set of conceptual spacecraft designs generated using the STS system's conceptual design method 200. In some scenarios, a user selects the spacecraft design and provides input to the STS system indicating the selection. In some scenarios, the STS system selects the spacecraft design based on specified criteria (e.g., a performance metric).

In step 304, the STS system determines whether any custom interfaces are needed. An interface permits at least one spacecraft component to integrate with another spacecraft component or with a device carried by the spacecraft (e.g., the spacecraft's payload). Some non-limiting examples of interfaces include mechanical interfaces, electrical interfaces, etc. An electrical interface (e.g., breakout board, payload interface board, motherboard, general interface board, etc.) facilitates electrical integration (e.g., coupling or communication) between spacecraft components and/or devices. A mechanical interface (e.g., bracket, hole, joint, etc.) facilitates mechanical integration (e.g., connection or coupling) between spacecraft components and/or devices. The STS system may determine that a custom interface between (or among) spacecraft components/devices is needed if the spacecraft design indicates that an interface between (or among) the components/devices is required and no commercial off-the-shelf (COTS) component suitable for providing such an interface is available. In some embodiments, the STS system uses the ME module to determine whether any custom mechanical interfaces are needed, and uses an electrical engineering (EE) module to determine whether any custom electrical interfaces are needed.

In step 306, the STS system designs any custom interfaces identified by the system at step 304. In some embodiments, the STS system uses the ME module to design any custom mechanical interfaces and uses the EE module to design any customer electrical interfaces.

In some embodiments, designing the custom interfaces includes generating the spacecraft frame. In some embodiments, stack-tray structural architecture enclosures for the entire spacecraft (excluding solar, antennas, and clamp-band) are generated. In some embodiments, mass-optimizing features (e.g., thickness variances, x-shaped framing, etc.) are added. For example, in some embodiments, rather than using a stack-tray architecture, generative design is used to produce a mass/load-path optimized frame.

In step 308, the STS system generates preliminary design plans for the spacecraft. In some embodiments, the STS system updates the conceptual design plans (e.g., CAD model) generated at step 210 of the conceptual design method 200 to incorporate the custom interfaces provided at step 306 of the preliminary design method 300. In some embodiments, the CAD-mass of the frame is determined and heuristic rules of the SE module for estimating frame mass are updated accordingly. In some embodiments, the enclosure arrangement design rules may be re-applied (e.g., by the ME module). For example, the enclosure arrangement design rules may be re-applied to update the design to include connector keep-out zones, cable routing constraints, access hole constraints, assembly clearance constraints, etc. In some embodiments, the updated design produced at step 308 visually resembles a PDR-level design. An example of a view of a PDR-level spacecraft design is shown in FIG. 3B.

In some embodiments, the STS system can automatically perform a final design method to generate a critical design review (CDR)-level spacecraft design based on a preliminary design (e.g., a preliminary design generated using the STS system's preliminary design method 300). This includes generating a digital twin including a collection of models that represent various components of a spacecraft. FIG. 3C illustrates various outputs of generating a digital twin when different components are sequentially added to the spacecraft design based on conceptual design plan.

In some embodiments, performing the final design method involves optimizing the frame and applying DFMA rules and/or DFAM rules to the frame's design. In some embodiments, applying DFMA and/or DFAM rules to the frame's design is an iterative process in which DFMA/DFAM rules are sequentially selected; the spacecraft design is checked for compliance with the selected rule; and, if the spacecraft design is not in compliance with the selected rule, one or more (e.g., all) steps of the conceptual design method 200 and/or the preliminary design method 300 are automatically performed again to update the design to comply with the selected rule. This process of applying DFMA/DFAM rules may continue until the spacecraft design complies with all applicable rules or until the STS system indicates that it is unable to generate a design that complies with one or more of the DFMA/DFAM rules.

### Some Specific Implementations in Spacecraft Design

Referring now to FIG. 4, an exemplary process 400 for selecting candidate components for a spacecraft is provided. The process 400 may be implemented by the disclosed STS system, for example, by the SE module in the system. For example, the SE module may use data codifying relationships between component specification parameters and mission parameters to select specific components included in the subsystems in the spacecraft design, as will be described in detail below. The process 400 will be described in detail with reference to some embodiments illustrated in FIGS. 5A-5D.

As illustrated in FIG. 4, the process 400 starts with an empty spacecraft 402, which is a default initial state for the spacecraft design. There is no component yet in the empty spacecraft. In the next, a series of subsystem components are sequentially added.

At step 404, a payload is inserted into the empty spacecraft 402 to get a spacecraft with the payload 406. The processing of inserting the payload includes retrieving a payload profile from a data store storing the payloads and other design related information or data. Specifically, referring to FIG. 5A, the payload file may include information such as the mass of the payload (e.g., 10 kg), power required by the payload (e.g., 35 W), transmission requirements (e.g., High). The payload information is stored in a structured database, so that the information for each aspect can be readily identified by the SE module, where the identified information for each aspect is then used in the spacecraft design.

For example, the information related to the transmission requirement can be used to select the proper communications subsystems in the spacecraft design, as shown in step 408 in FIG. 4. If the transmission requirement is low, UHF and S-Band radios/antenna are then inserted at step 410. On the other hand, if the transmission requirement is medium, UHF, S, and X-band radios/antennas are inserted at step 412. Similarly, if the transmission requirement is high, UHF, S, and AK-band radios/antennas are inserted at step 414.

As described earlier, the automated and codified rules-based design is employed by the SE module in the insertion of the communications subsystem in the design. For example, as shown in FIG. 5B, the codified rules implemented by the SE module may include a set of if-then or other forms of rules for selection of proper communications subsystem components. According to one codified rule, the ST module does not insert additional components if the transmission requirement is low, as shown in FIG. 5B. This is because the UHF and S-band radios/antennas are automatically added by default no natter what the transmission requirement is, as also shown in FIG. 5B. On the other hand, when the transmission requirement is not low, additional components are automatically added. For example, according to the codified rules included in the system, when the transmission requirement is high, certain KA-band radios/antennas are then inserted into the spacecraft design, as illustrated in FIG. 5B.

It should be noted that, when inserting the KA-band radios/antennas, more than one option may be available. Accordingly, more than one spacecraft design can be generated. For example, as illustrated in FIG. 5B, for spacecraft 1, KA-band radio 3 and KA-band antenna 2 are inserted, while for spacecraft 2, KA-band radio 1 and KA-band antenna 1 are inserted into the design. Depending on the availability of KA-band radios/antennas, there may be additional spacecraft designs available, which are not limited in the present disclosure.

Referring back to FIG. 4, after inserting the communications subsystem at step 410/412/414, a set of spacecraft designs with payload and communications subsystems 416 are obtained. In the next, a propulsion subsystem is added to each spacecraft design at step 418. More specifically, 0-2 thrusters are inserted into each spacecraft design in this step. For example, as shown in FIG. 5C, for the spacecraft design spacecraft 1, a thruster 1 and a thruster 3 are inserted, for another spacecraft design spacecraft 2, 2x thruster 2 are inserted, while for another spacecraft design spacecraft 3, a single thruster 3 is inserted.

A thruster is a spacecraft propulsion device used for orbital station-keeping, attitude control, or long-duration, low-thrust acceleration, often as part of a reaction control system. Some spacecrafts may not use thrusters but use other propulsion devices such as liquid apogee engine or apogee kick motor. Accordingly, if no thruster is inserted into a spacecraft design, the SE module may automatically select one of these other propulsion devices for the propulsion subsystem in the spacecraft design. Referring back to FIG. 4, after inserting a propulsion subsystem, a set of spacecraft designs with payload, communications, and propulsion subsystems 420 are obtained.

In the next, the ADCS and GN&C subsystem is inserted, which includes components used for position determination and attitude determination and for control based on the determinations. Specifically, based on the pointing knowledge requirement determined at step 422, 0-2 star trackers are added at steps 424/426/428. For example, if the pointing knowledge requirement is low, 0 star tacker is added, if the pointing knowledge requirement is medium, 1 star tracker is added, and if the pointing knowledge requirement is high, 2 star trackers are added. Star trackers generally determine the location and attitude of a spacecraft by analyzing the placement of the surrounding stars relative to the payload. If a spacecraft needs to know really well how it is oriented relative to a target, two star trackers may be required. Otherwise, 1 or 0 star tracker is needed for a designed spacecraft.

At step 430, 1-3 magnetic torquers (or magnetorquers) are added to each spacecraft design. A magnetic torquer is a spacecraft system for attitude control, detumbling, and stabilization built from electromagnetic coils. The number of magnetorquers added depends on how many coils that specific component has. At step 432, 0-4 reaction wheels are added to each spacecraft design. Reaction wheels are essentially flywheels that enable repositioning of controllable space vehicles and spacecrafts while they are in orbit. While reaction wheels are easily exploited because they can generate a torque in any desired direction at any time, magnetorquers rely on a more subtle principle: by generating a magnetic momentum that interacts with the geomagnetic field, a torque is created. In some embodiments, additional ADCS/GN&C components can be added to a spacecraft design. Once these various position and attitude determination and control components are added, a set of spacecraft designs 434 with payload, communications, propulsion, and ADCS/GN&C subsystems are obtained.

Referring to FIG. 5D, when adding the ADCS/GN&C components to a spacecraft design 420, for one example spacecraft 1, 1x magnetorquer 2, 3x reaction wheel 1, 2x star tracker 1 are added. For another example spacecraft 2, 3x magnetorquer 1, 4x reaction wheels 3, and 2x star tracker 1 are added. From this and other figures, it can be seen an exponential growth of the number of spacecrafts with every subsystem (or component) added during the evolution of the spacecraft design.

In the next, the CDH subsystem is added. Specifically, at step 436, a storage device is added to make sure that enough memory is added to satisfy the requirement by the space services department (SSD). In one example, a minimum of 20 GB RAM is required for a spacecraft server to function. In addition, a minimum of 4 GB RAM of swap space is also recommended. Spacecraft running with less RAM than the minimum value might not operate correctly.

At step 438, an OBC is added. The OBC is the brain of the spacecraft. OBC is responsible for implementation of control law, processing associated with payload, data packeting activities associated with communication, monitoring load health status, handling of data storage etc. The processor needs to interface with various sensors, actuators present onboard to acquire data to perform its activities and respond accordingly through actuators. Scheduling the activities of the processor is essential due to the number of tasks it has to perform. When adding an OBC, it needs to ensure that the added OBC fulfills the memory requirements and has compatible interfaces with the aforementioned components. Once the CDH subsystem is added, a set of spacecraft designs 440 with payload, communications, propulsion, ADCS/GN&C, and CDH subsystems are obtained.

In the next, the power subsystem is added. Specifically, at step 442, a set of solar panels are added to provide a mean power consumption for a spacecraft. Typically, 200 to 800 watts of electricity is generated by sunlight and the added solar panels. Depending on the requirement, a higher or lower amount of electricity may be required for a spacecraft, and thus the solar panels added to a design can be adjusted accordingly. At step 444, an appropriate power control & distribution unit (PCDU) compatible with the selected solar panel generation is added. Once the power system is added, a set of spacecraft designs 446 with payload, communications, propulsion, ADCS/GN&C, CDH, and power subsystems are obtained.

In the next, the structure subsystem is added to a spacecraft design. The structure subsystem provides the overall mechanical integrity of the spacecraft. It must ensure that all spacecraft components are supported, and that they can withstand handling and launch loads as well as flight in freefall and during operation of propulsive components. To add the structure subsystem, a custom structure is added at step 448, where the added structure may have a mass that is around 80% (or another different value) or the total weight of a designed spacecraft. Once the structure subsystem is added, a set of spacecrafts 450 with payload, communications, ADCS/GN&C, CDH, power, and structure subsystems are obtained.

At step 452, the obtained set of spacecraft designs may be further filtered to identify the ones that meet the requirements of the mission, which then generates a final list of viable spacecrafts that meet the requirements. In some embodiments, when adding each subsystem or component included in each subsystem, the specific requirements for each subsystem or component included therein may be already taken into account. Accordingly, the step 452 may be not necessarily performed at the end of the design process 400. Although not shown, in some embodiments, the obtained list of viable spacecraft designs may be further ranked according to certain performance metrics (e.g., cost, power, mass, etc.).

It should be noted that, in the above described process 400, the addition of subsystem components is not limited to the order illustrated in FIG. 4, but can be in other different orders. For example, the propulsion subsystem may be added before the communications subsystem. For another example, reaction wheels may be added before the magnetorquer.

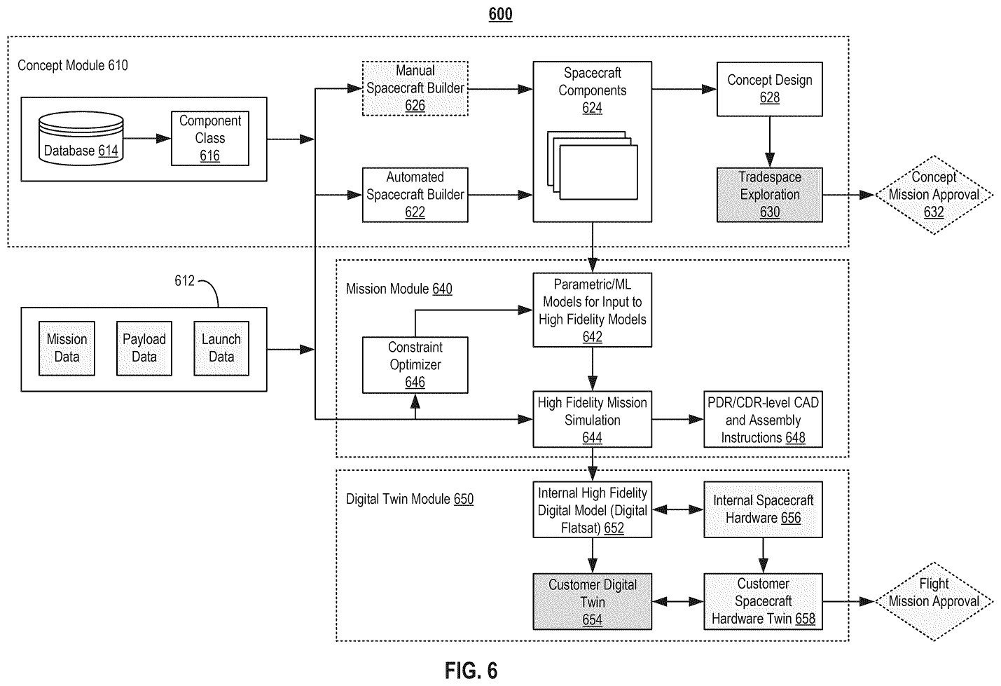

In some embodiments, based on the components selected in the conceptual design, the STS system further arranges CAD files associated with the selected components to generate a preliminary spacecraft design (e.g., a CAD visualization of the spacecraft including spacecraft components, enclosures, and frame) for each filtered viable spacecraft. In some embodiments, the STS system automatically performs a final design method to generate a critical design review (CDR)-level spacecraft design based on a preliminary design (e.g., a preliminary design generated using the STS system's preliminary design method 300), as described earlier in FIG. 3A, and as further described below in FIG. 6.

### System Architecture for Spacecraft Design

In some embodiments, to achieve the above described different methods/processes, the STS system 600 may be configured to include specific modules or software components for achieving the different functions described above. Exemplary modules include but are not limited to a concept module, a mission module, and a digital twin module, as illustrated in FIG. 6. In some embodiments, each of the concept module, mission module, and digital twin module may be configured to implement partial or full functions performed by the SE, ME, and EE modules as described earlier. In the following, each of the concept module, mission module, and digital twin module is illustrated according to functions or process flow shown in FIG. 6.

Specifically, the concept module 610 is configured to use techniques including parametrization, knowledge-based digitization, scalable computation, COTS subsystem, etc., to generate a set of conceptual spacecraft designs based on the mission requirements and/or metrics from user inputs. For example, mission, payload, and launch data 612 may be inputs provided by a customer. This information is then used by an automated spacecraft builder 622, along with a component database 614 and component categories 616 to select subsystems or components 624 for a spacecraft, to ensure subsystem compatibility. This results in a set of conceptual designs 628, each of which includes a block diagram as well as mass and power budgets and a preliminary cost for the designed spacecraft. Once customer approval 632 is obtained for the concept mission, the automated system starts on the detailed design of the spacecraft, which includes the generation of a collection of CADs representing the structures of the subsystems or components included in the conceptual design. In some embodiments, the automated generated CADs (together may be referred to as a CAD model) may be further subject to a series of analyses or simulations to evaluate the performance of the CAD model. Such analyses may include but are not limited to automated thermal analysis, automated structural analysis, and orbital simulations, as further described in detail with reference to the mission module 640.

In some embodiments, a manual spacecraft builder 626 may implement a design process in parallel (or at a delayed stage) with the automated spacecraft builder 622, whereas the manual spacecraft builder may implement a process reliant on individual know-how and often requiring SMEs. The purpose of the manual spacecraft builder may be used to further evaluate the automated generated CAD model to some extent.

In some embodiments, the component database 614 may include a data set of specification parameters 616 for each component. All of the information in the component database 614/616 may facilitate the automated spacecraft builder 622 in generating the conceptual design, such as the block diagram, mass and power budget, and so on. In some embodiments, the components in the database may be organized in class 616 for easier processing by the automated spacecraft builder 622 and the manual spacecraft builder 626 in generating the conceptual designs 628.

In some embodiments, the concept module 610 is configured to implement certain parametric design techniques to achieve the automated spacecraft conceptual design, as described earlier. This includes capturing the engineering knowledge in the form of codified rules and/or constraints, where each codified rule describes a refinement step in the design process or a safety concern. For example, in the process of adding the ADCS/GN&C subsystem in the concept design (as described in FIG. 4), there may be different approaches to implementing the attitude control system of a spacecraft, depending on factors such as the required pointing accuracy, pointing direction, slew maneuvers, and orbit altitude of the mission. This decision making process is manifested as a set of rules by the disclosed concept module 610, where each rule embodies a possible approach to fulfilling the requirements of the ADCS/GN&C subsystem. In some embodiments, instead of being driven by the mission requirements (e.g., mission data 612), codified rules may be also driven by the presence of certain components in the design. For example, if a requirement driven rule has led to a selection of a magnetic torque rod to perform attitude control or momentum dumping for a spacecraft design, the presence of this component may trigger an additional rule that attaches a magnetometer that is necessary for the torque rod's operation.

In some embodiments, by coding engineering knowledge into sets of rules, the rule-based approach enables the concept module 610 (e.g., the automated spacecraft builder 622) to automatically generate multiple alternative designs. The optimization algorithm then drives the choice of the design towards better options given the mission requirements and/or metrics provided by users. In some embodiments, a new rule or a component once developed can be added to the database, which allows it to be immediately considered by the search algorithm included in the automated spacecraft builder 622. This then allows the concept module 610 to take advantage of the state of the art hardware/knowledge when generating spacecraft designs (e.g., by coding new rules for the new state of art hardware and/or knowledge). In some embodiments, by automating the design process with the codified rules, the concept module 610 speeds up the conceptual spacecraft design and improves the confidence level of the spacecraft design to meet the mission objectives.

In some embodiments, the concept module 610 may be further configured to allow real-time tradespace exploration (e.g., analysis of the tradeoffs among resources, costs, and provisioning for different spacecraft designs in the design space) at step 630 and design optimization along different parameters (e.g., lead time, cost, capability, technology readiness level (TRL), etc.) in the conceptual design process.

It should be noted that the component database 614 for the STS system disclosed herein may be customized databases specific to an organization or entity, or may be any 3rd party databases, such as the database from Aerospace Corp. for different thruster subsystems. The automated design system disclosed herein may be introduced to a 3rd party database with a translator. From there, the automated design system may then use the external database as well as its own customized database for the subsystem selection and block diagram generation.

In some embodiments, the conceptual designs 628, once approved at step 632, are further subject to the automated high fidelity mission simulations for verification and/or possible optimization, as further described in detail below.

Referring now to the mission module 640, different models or platforms 642 are used in the high-fidelity mission simulations for verification (at step 644) of a conceptual design, where these simulations include automated parametrization and explainable machine learning-assisted functions. For example, for orbital simulation, a specifically configured system took kit (STK) or another different orbital simulation software tool may be used, which models complex systems inside a realistic and time-dynamic three-dimensional simulation that includes high-resolution terrain, imagery, RF environments, and more. STK application allows to select, build, or import precise models of ground, sea, air, and space assets and combine them to represent existing or proposed systems, and allows to simulate the entire system-of-systems in action, at any location and at any time, to gain a clear understanding of its behavior and mission performance. For another example, for structural simulation, Ansys® may be used, which offers structural analysis software solutions that enable engineers of all levels and backgrounds to solve complex structural engineering problems faster and more efficiently. For example, using Ansys, engineers may perform finite element analyses (FEA), finite difference method (FDM), customize and automate solutions for structural mechanics challenges, and analyze multiple design scenarios. By using Ansys early in the design cycle, it allows to save costs, and reduce the number of design cycles. For another example, for DFMA, computer aided three-dimensional interactive application (CATIA) may be used, which is a full software suite that incorporates CAD, CAE (computer-aided engineering), and CAM (computer-aided manufacturing).

According to some embodiments, the high fidelity mission simulations also include a thermal simulation. A platform such as SINDA/FLUINT may be used for the desired thermal simulation. SINDA/FLUINT is a comprehensive, generalized tool for simulating complex thermal/fluid systems such as those found in the electronics, automotive, petrochemical, power generation, medical, and aerospace industries. It is a NASA standard software system for thermohydraulic analysis, which provides computational simulation of interacting thermal and fluid effects in designs modeled as heat transfer and fluid flow networks. It is also used to design and analyze aerospace systems.

In some embodiments, during the high fidelity mission simulations, there may be problems, e.g., conflicts found in the arrangements of the selected components in the conceptual design. Accordingly, the mission module 640 disclosed herein additionally includes a constraint optimizer 646 for design optimization.

According to some embodiments, the constraint optimizer 646 includes an optimization engine that is configured to use constraint-based planning techniques to generate multiple alternative designs if problems are found in a current design. In one example, the optimization engine included in the constraint optimizer 646 may be configured to prune the design space both in the requirements-to-design direction (as described in FIG. 4) and possible-design-to-achieve-goals direction, which speeds up the search for candidate alternative components for the subsystems included in a spacecraft design. In some embodiments, the constrain reasoning/planning-based engine in the constraint optimizer 646 uses procedural constraints, which allows to integrate third party software into the search process. Such tight integration may allow for earlier identification of possible dead ends, and thus shorter time in the design optimization process.

According to some embodiments, the outcome of the automated spacecraft design after simulation-based verification and/or constraint-based optimization includes a collection of preliminary design review (PDR)/critical design review (CDR)-level CAD 648. In some embodiments, the mission module 640 may also generate certain assembly instructions accompanying the spacecraft design at 648.

Referring now to the digital twin module 650, it may refer to a process or platform that assembles component models to obtain a virtual representation of a designed spacecraft that is as close as possible to a real spacecraft. For example, as illustrated in FIG. 6, the digital twin module 650 may be configured to assemble a collection of high-fidelity, validated, manufacturable CAD and the system functional model, thermal, structural, and orbital analyses for the specific spacecraft design to form a digital spacecraft, also referred to as digital twin 652. In some embodiments, this digital twin 652 (i.e., a high-fidelity digital representation of the spacecraft system) may co-evolve with a rapidly integrated benchtop hardware twin 656. This digital twin 652, with twinned hardware-in-the-loop architecture 656, enables early system prototyping and rapid hardware evolution and automatic updating of the digital twin, thereby mitigating integration challenges later in the assembly, integration, and test (AIT) process. In some embodiments, a customer version of digital twin 654 is also generated, which co-evolves with the customer-specific hardware twin 658.

While not shown, in some embodiments, once the above-described automated analyses are complete or close to convergence, the DFMA and DFAM may start, as described earlier. The DFMA module may supply a set of additions and constraints (which may be heuristic rules) that will inform the structural design. If the design warrants additive manufacturing, the DFAM module may take the revised structural design, determine the load paths, and proceed to a generative optimizer that will produce an optimized design, to make it manufacturable by additive manufacturing.

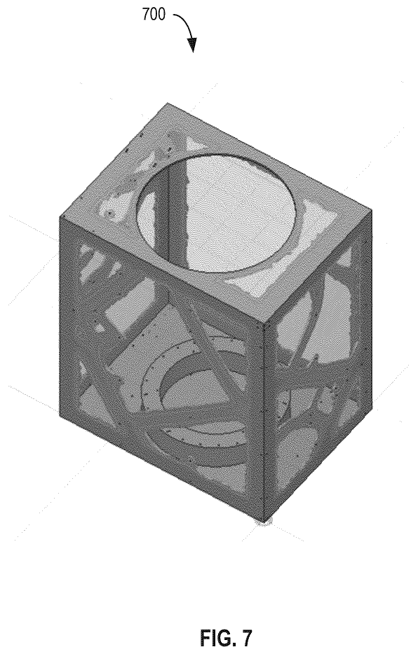

FIG. 7 illustrates an example outcome 700 of a generative spacecraft design for additive manufacturing, in accordance with some embodiments. In the figure, the design is optimized by the generative optimizer by automatically generating and comparing multiple design options to find one or more ideal, best-fit solutions. This may include quick iterations of hundreds or thousands of possible optimized designs through CAD geometry based simulations, resulting in one or more truly optimized solutions that can be then 3D printed, as shown in FIG. 7.

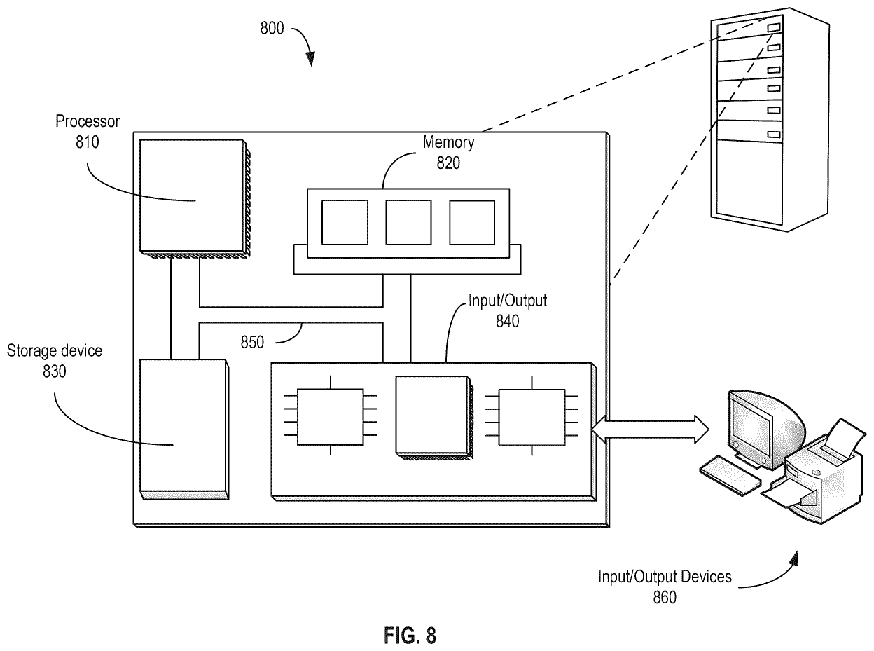

In some embodiments, the concept module, mission module, and digital twin module may be a part of a software application that runs on a computer system, as will be described in detail in FIG. 8.

### Additional Embodiments

FIG. 8 is a block diagram of an example computer system 800 that may be used in implementing the technology described in this document. General-purpose computers, network appliances, mobile devices, or other electronic systems may also include at least portions of the system 800. The system 800 includes a processor 810, a memory 820, a storage device 830, and an input/output device 840. Each of the components 810, 820, 830, and 840 may be interconnected, for example, using a system bus 850. The processor 810 is capable of processing instructions for execution within the system 800. In some implementations, the processor 810 is a single-threaded processor. In some implementations, the processor 810 is a multi-threaded processor. In some implementations, the processor 810 is a programmable (or reprogrammable) general purpose microprocessor or microcontroller. The processor 810 is capable of processing instructions stored in the memory 820 or on the storage device 830.

The memory 820 stores information within the system 800. In some implementations, the memory 820 is a non-transitory computer-readable medium. In some implementations, the memory 820 is a volatile memory unit. In some implementations, the memory 820 is a non-volatile memory unit.

The storage device 830 is capable of providing mass storage for the system 800. In some implementations, the storage device 830 is a non-transitory computer-readable medium. In various different implementations, the storage device 830 may include, for example, a hard disk device, an optical disk device, a solid-date drive, a flash drive, or some other large capacity storage device. For example, the storage device may store long-term data (e.g., database data, file system data, etc.). The input/output device 840 provides input/output operations for the system 800. In some implementations, the input/output device 840 may include one or more network interface devices, e.g., an Ethernet card, a serial communication device, e.g., an RS-232 port, and/or a wireless interface device, e.g., an 802.11 card, a 3G wireless modem, or a 4G wireless modem. In some implementations, the input/output device may include driver devices configured to receive input data and send output data to other input/output devices, e.g., keyboard, printer and display devices 860. In some examples, mobile computing devices, mobile communication devices, and other devices may be used.

In some implementations, at least a portion of the approaches described above may be realized by instructions that upon execution cause one or more processing devices to carry out the processes and functions described above. Such instructions may include, for example, interpreted instructions such as script instructions, or executable code, or other instructions stored in a non-transitory computer readable medium. The storage device 830 may be implemented in a distributed way over a network, for example as a server farm or a set of widely distributed servers, or may be implemented in a single computing device.

Although an example processing system has been described in FIG. 8, embodiments of the subject matter, functional operations and processes described in this specification can be implemented in other types of digital electronic circuitry, in tangibly-embodied computer software or firmware, in computer hardware, including the structures disclosed in this specification and their structural equivalents, or in combinations of one or more of them. Embodiments of the subject matter described in this specification can be implemented as one or more computer programs, i.e., one or more modules of computer program instructions encoded on a tangible nonvolatile program carrier for execution by, or to control the operation of, a data processing apparatus. Alternatively or in addition, the program instructions can be encoded on an artificially generated propagated signal, e.g., a machine-generated electrical, optical, or electromagnetic signal that is generated to encode information for transmission to suitable receiver apparatus for execution by a data processing apparatus. The computer storage medium can be a machine-readable storage device, a machine-readable storage substrate, a random or serial access memory device, or a combination of one or more of them.

The term “system” may encompass all kinds of apparatus, devices, and machines for processing data, including by way of example a programmable processor, a computer, or multiple processors or computers. A processing system may include special purpose logic circuitry, e.g., an FPGA (field programmable gate array), an ASIC (application specific integrated circuit), or a programmable general purpose microprocessor or microcontroller. A processing system may include, in addition to hardware, code that creates an execution environment for the computer program in question, e.g., code that constitutes processor firmware, a protocol stack, a database management system, an operating system, or a combination of one or more of them.

A computer program (which may also be referred to or described as a program, software, a software application, a module, a software module, a script, or code) can be written in any form of programming language, including compiled or interpreted languages, or declarative or procedural languages, and it can be deployed in any form, including as a standalone program or as a module, component, subroutine, or other unit suitable for use in a computing environment. A computer program may, but need not, correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program can be deployed to be executed on one computer or on multiple computers that are located at one site or distributed across multiple sites and interconnected by a communication network.

The processes and logic flows described in this specification can be performed by one or more programmable computers executing one or more computer programs to perform functions by operating on input data and generating output. The processes and logic flows can also be performed by, and apparatus can also be implemented as, special purpose logic circuitry, e.g., an FPGA, an ASIC, or a programmable general purpose microprocessor or microcontroller.

Computers suitable for the execution of a computer program can include, by way of example, general or special purpose microprocessors or both, or any other kind of central processing unit. Generally, a central processing unit will receive instructions and data from a read-only memory or a random access memory or both. A computer generally includes a central processing unit for performing or executing instructions and one or more memory devices for storing instructions and data. Generally, a computer will also include, or be operatively coupled to receive data from or transfer data to, or both, one or more mass storage devices for storing data, e.g., magnetic disks, magneto optical disks, or optical disks. However, a computer need not have such devices. Moreover, a computer can be embedded in another device, e.g., a mobile telephone, a personal digital assistant (PDA), a mobile audio or video player, a game console, a Global Positioning System (GPS) receiver, or a portable storage device (e.g., a universal serial bus (USB) flash drive), to name just a few.

Computer readable media suitable for storing computer program instructions and data include all forms of nonvolatile memory, media and memory devices, including by way of example semiconductor memory devices, e.g., EPROM, EEPROM, and flash memory devices; magnetic disks, e.g., internal hard disks or removable disks; magneto optical disks; and CD-ROM and DVD-ROM disks. The processor and the memory can be supplemented by, or incorporated in, special purpose logic circuitry.

To provide for interaction with a user, embodiments of the subject matter described in this specification can be implemented on a computer having a display device, e.g., a CRT (cathode ray tube) or LCD (liquid crystal display) monitor, for displaying information to the user and a keyboard and a pointing device, e.g., a mouse or a trackball, by which the user can provide input to the computer. Other kinds of devices can be used to provide for interaction with a user as well; for example, feedback provided to the user can be any form of sensory feedback, e.g., visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user's user device in response to requests received from the web browser.

Embodiments of the subject matter described in this specification can be implemented in a computing system that includes a back end component, e.g., a data server, or that includes a middleware component, e.g., an application server, or that includes a front end component, e.g., a client computer having a graphical user interface or a Web browser through which a user can interact with an implementation of the subject matter described in this specification, or any combination of one or more such back end, middleware, or front end components. The components of the system can be interconnected by any form or medium of digital data communication, e.g., a communication network. Examples of communication networks include a local area network (“LAN”) and a wide area network (“WAN”), e.g., the Internet.

The computing system can include clients and servers. A client and server are generally remote from each other and typically interact through a communication network. The relationship between client and server arises by virtue of computer programs running on the respective computers and having a client-server relationship with each other.

While this specification contains many specific implementation details, these should not be construed as limitations on the scope of what may be claimed, but rather as descriptions of features that may be specific to particular embodiments. Certain features that are described in this specification in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

In addition, programs that implement various aspects of some embodiments may be accessed from a remote location (e.g., a server) over a network. Such data and/or programs may be conveyed through any of a variety of machine-readable medium including, but not limited to: magnetic media such as hard disks, floppy disks, and magnetic tape; optical media such as CD-ROMs and holographic devices; magneto-optical media; and hardware devices that are specially configured to store or to store and execute program code, such as application specific integrated circuits (ASICs), programmable logic devices (PLDs), flash memory devices, and ROM and RAM devices. Some embodiments may be encoded upon one or more non-transitory, computer-readable media with instructions for one or more processors or processing units to cause steps to be performed. It shall be noted that the one or more non-transitory, computer-readable media shall include volatile and non-volatile memory. It shall also be noted that alternative implementations are possible, including a hardware implementation or a software/hardware implementation. Hardware-implemented functions may be realized using ASIC(s), programmable arrays, digital signal processing circuitry, or the like. Accordingly, the “means” terms in any claims are intended to cover both software and hardware implementations. Similarly, the term “computer-readable medium or media” as used herein includes software and/or hardware having a program of instructions embodied thereon, or a combination thereof. With these implementation alternatives in mind, it is to be understood that the figures and accompanying description provide the functional information one skilled in the art would require to write program code (i.e., software) and/or to fabricate circuits (i.e., hardware) to perform the processing required.

It shall be noted that some embodiments may further relate to computer products with a non-transitory, tangible computer-readable medium that has computer code thereon for performing various computer-implemented operations. The medium and computer code may be those specially designed and constructed for the purposes of the techniques described herein, or they may be of the kind known or available to those having skill in the relevant arts. Examples of tangible, computer-readable media include, but are not limited to: magnetic media such as hard disks, floppy disks, and magnetic tape; optical media such as CD-ROMs and holographic devices; magneto-optical media; and hardware devices that are specially configured to store or to store and execute program code, such as application specific integrated circuits (ASICs), programmable logic devices (PLDs), flash memory devices, and ROM and RAM devices. Examples of computer code include machine code, such as produced by a compiler, and files containing higher level code that is executed by a computer using an interpreter. Some embodiments may be implemented in whole or in part as machine-executable instructions that may be in program modules that are executed by a processing device. Examples of program modules include libraries, programs, routines, objects, components, and data structures. In distributed computing environments, program modules may be physically located in settings that are local, remote, or both.

One skilled in the art will recognize no computing system or programming language is critical to the practice of the techniques described herein. One skilled in the art will also recognize that a number of the elements described above may be physically and/or functionally separated into sub-modules or combined together.

In embodiments, aspects of the techniques described herein (e.g., training a risk assessment model, using a risk assessment model to assess the risk associated with a commit request, performing one or more (e.g., all) of the steps of the methods described herein, etc.) may be implemented using machine learning and/or artificial intelligence technologies.

“Machine learning” generally refers to the application of certain techniques (e.g., pattern recognition and/or statistical inference techniques) by computer systems to perform specific tasks. Machine learning techniques may be used to build models based on sample data (e.g., “training data”) and to validate the models using validation data (e.g., “testing data”). The sample and validation data may be organized as sets of records (e.g., “observations” or “data samples”), with each record indicating values of specified data fields (e.g., “independent variables,” “inputs,” “features,” or “predictors”) and corresponding values of other data fields (e.g., “dependent variables,” “outputs,” or “targets”). Machine learning techniques may be used to train models to infer the values of the outputs based on the values of the inputs. When presented with other data (e.g., “inference data”) similar to or related to the sample data, such models may accurately infer the unknown values of the targets of the inference data set.

A feature of a data sample may be a measurable property of an entity (e.g., person, thing, event, activity, etc.) represented by or associated with the data sample. A value of a feature may be a measurement of the corresponding property of an entity or an instance of information regarding an entity. Features can also have data types. For instance, a feature can have an image data type, a numerical data type, a text data type (e.g., a structured text data type or an unstructured (“free”) text data type), a categorical data type, or any other suitable data type. In general, a feature's data type is categorical if the set of values that can be assigned to the feature is finite.

As used herein, “model” may refer to any suitable model artifact generated by the process of using a machine learning algorithm to fit a model to a specific training data set. The terms “model,” “data analytics model,” “machine learning model” and “machine learned model” are used interchangeably herein.

As used herein, the “development” of a machine learning model may refer to construction of the machine learning model. Machine learning models may be constructed by computers using training data sets. Thus, “development” of a machine learning model may include the training of the machine learning model using a training data set. In some cases (generally referred to as “supervised learning”), a training data set used to train a machine learning model can include known outcomes (e.g., labels or target values) for individual data samples in the training data set. For example, when training a supervised computer vision model to detect images of cats, a target value for a data sample in the training data set may indicate whether or not the data sample includes an image of a cat. In other cases (generally referred to as “unsupervised learning”), a training data set does not include known outcomes for individual data samples in the training data set.

Following development, a machine learning model may be used to generate inferences with respect to “inference” data sets. For example, following development, a computer vision model may be configured to distinguish data samples including images of cats from data samples that do not include images of cats. As used herein, the “deployment” of a machine learning model may refer to the use of a developed machine learning model to generate inferences about data other than the training data.

“Artificial intelligence” (AI) generally encompasses any technology that demonstrates intelligence. Applications (e.g., machine-executed software) that demonstrate intelligence may be referred to herein as “artificial intelligence applications,” “AI applications,” or “intelligent agents.” An intelligent agent may demonstrate intelligence, for example, by perceiving its environment, learning, and/or solving problems (e.g., taking actions or making decisions that increase the likelihood of achieving a defined goal). In many cases, intelligent agents are developed by organizations and deployed on network-connected computer systems so users within the organization can access them. Intelligent agents are used to guide decision-making and/or to control systems in a wide variety of fields and industries, e.g., security; transportation; risk assessment and management; supply chain logistics; and energy management. Intelligent agents may include or use models.

Some non-limiting examples of AI application types may include inference applications, comparison applications, and optimizer applications. Inference applications may include any intelligent agents that generate inferences (e.g., predictions, forecasts, etc.) about the values of one or more output variables based on the values of one or more input variables. In some examples, an inference application may provide a recommendation based on a generated inference. For example, an inference application for a lending organization may infer the likelihood that a loan applicant will default on repayment of a loan for a requested amount, and may recommend whether to approve a loan for the requested amount based on that inference. Comparison applications may include any intelligent agents that compare two or more possible scenarios. Each scenario may correspond to a set of potential values of one or more input variables over a period of time. For each scenario, an intelligent agent may generate one or more inferences (e.g., with respect to the values of one or more output variables) and/or recommendations. For example, a comparison application for a lending organization may display the organization's predicted revenue over a period of time if the organization approves loan applications if and only if the predicted risk of default is less than 20% (scenario #1), less than 10% (scenario #2), or less than 5% (scenario #3). Optimizer applications may include any intelligent agents that infer the optimum values of one or more variables of interest based on the values of one or more input variables. For example, an optimizer application for a lending organization may indicate the maximum loan amount that the organization would approve for a particular customer.

As used herein, “data analytics” may refer to the process of analyzing data (e.g., using machine learning models, artificial intelligence, models, or techniques) to discover information, draw conclusions, and/or support decision-making. Species of data analytics can include descriptive analytics (e.g., processes for describing the information, trends, anomalies, etc. in a data set), diagnostic analytics (e.g., processes for inferring why specific trends, patterns, anomalies, etc. are present in a data set), predictive analytics (e.g., processes for predicting future events or outcomes), and prescriptive analytics (processes for determining or suggesting a course of action).

Data analytics tools are used to guide decision-making and/or to control systems in a wide variety of fields and industries, e.g., security; transportation; risk assessment and management; supply chain logistics; and energy management. The processes used to develop data analytics tools suitable for carrying out specific data analytics tasks generally include steps of data collection, data preparation, feature engineering, model generation, and/or model deployment.

### Terminology

The phrasing and terminology used herein is for the purpose of description and should not be regarded as limiting.

Measurements, sizes, amounts, and the like may be presented herein in a range format. The description in range format is provided merely for convenience and brevity and should not be construed as an inflexible limitation on the scope of the invention. Accordingly, the description of a range should be considered to have specifically disclosed all the possible subranges as well as individual numerical values within that range. For example, description of a range such as 1-20 meters should be considered to have specifically disclosed subranges such as 1 meter, 2 meters, 1-2 meters, less than 2 meters, 10-11 meters, 10-12 meters, 10-13 meters, 10-14 meters, 11-12 meters, 11-13 meters, etc.

Furthermore, connections between components or systems within the figures are not intended to be limited to direct connections. Rather, data or signals between these components may be modified, re-formatted, or otherwise changed by intermediary components. Also, additional or fewer connections may be used. The terms “coupled,” “connected,” or “communicatively coupled” shall be understood to include direct connections, indirect connections through one or more intermediary devices, wireless connections, and so forth.

Reference in the specification to “one embodiment,” “preferred embodiment,” “an embodiment,” “some embodiments,” or “embodiments” means that a particular feature, structure, characteristic, or function described in connection with the embodiment is included in at least one embodiment of the invention and may be in more than one embodiment. Also, the appearance of the above-noted phrases in various places in the specification is not necessarily referring to the same embodiment or embodiments.

The use of certain terms in various places in the specification is for illustration purposes only and should not be construed as limiting. A service, function, or resource is not limited to a single service, function, or resource; usage of these terms may refer to a grouping of related services, functions, or resources, which may be distributed or aggregated.

Furthermore, one skilled in the art shall recognize that: (1) certain steps may optionally be performed; (2) steps may not be limited to the specific order set forth herein; (3) certain steps may be performed in different orders; and (4) certain steps may be performed simultaneously or concurrently.

The term “approximately”, the phrase “approximately equal to”, and other similar phrases, as used in the specification and the claims (e.g., “X has a value of approximately Y” or “X is approximately equal to Y”), should be understood to mean that one value (X) is within a predetermined range of another value (Y). The predetermined range may be plus or minus 20%, 10%, 5%, 3%, 1%, 0.1%, or less than 0.1%, unless otherwise indicated.

The indefinite articles “a” and “an,” as used in the specification and in the claims, unless clearly indicated to the contrary, should be understood to mean “at least one.” The phrase “and/or,” as used in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements).

As used in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements).

The use of “including,” “comprising,” “having,” “containing,” “involving,” and variations thereof, is meant to encompass the items listed thereafter and additional items.

Use of ordinal terms such as “first,” “second,” “third,” etc., in the claims to modify a claim element does not by itself connote any priority, precedence, or order of one claim element over another or the temporal order in which acts of a method are performed. Ordinal terms are used merely as labels to distinguish one claim element having a certain name from another element having a same name (but for use of the ordinal term), to distinguish the claim elements.

Particular embodiments of the subject matter have been described. Other embodiments are within the scope of the following claims. For example, the actions recited in the claims can be performed in a different order and still achieve desirable results. As one example, the processes depicted in the accompanying figures do not necessarily require the particular order shown, or sequential order, to achieve desirable results. In certain implementations, multitasking and parallel processing may be advantageous. Other steps or stages may be provided, or steps or stages may be eliminated, from the described processes. Accordingly, other implementations are within the scope of the following claims.

It will be appreciated by those skilled in the art that the preceding examples and embodiments are exemplary and not limiting to the scope of the present disclosure. It is intended that all permutations, enhancements, equivalents, combinations, and improvements thereto that are apparent to those skilled in the art upon a reading of the specification and a study of the drawings are included within the true spirit and scope of the present disclosure. It shall also be noted that elements of any claims may be arranged differently including having multiple dependencies, configurations, and combinations.

Having thus described several aspects of at least one embodiment of this invention, it is to be appreciated that various alterations, modifications, and improvements will readily occur to those skilled in the art. Such alterations, modifications, and improvements are intended to be part of this disclosure, and are intended to be within the spirit and scope of the invention. Accordingly, the foregoing description and drawings are by way of example only.

What is claimed is:

1. A method for automated spacecraft design, the method comprising:
receiving mission parameters provided by a client for spacecraft design;
generating one or more concept designs based on the received mission parameters, each concept design including one or more components selected for each subsystem included in a designed spacecraft;
for each concept design, generating a computer aided design (CAD) model including a collection of CADs representing structures of the one or more components selected for each subsystem included in the designed spacecraft;
performing a series of analyses or simulations to evaluate a performance of the CAD model; and
generating a digital twin representing a virtual representation of the designed spacecraft.

2. The method of claim 1, wherein the one or more components are automatically selected for each subsystem included in the designed spacecraft by using a set of codified rules capturing engineering knowledge involved in the spacecraft design.

3. The method of claim 2, wherein the set of codified rules are driven by the mission parameters for the spacecraft design.

4. The method of claim 2, wherein the set of codified rules are driven by a presence of certain components in each design concept.

5. The method of claim 1, wherein generating the CAD model for each concept design comprises:
importing the collection of CADs representing structures of the one or more components into a CAD environment,
automatically designing an enclosure for at least one of the one or more components; and
generating a CAD-based model of a spacecraft and combining the CAD models of the one or more components to generate a preliminary spacecraft design for the concept design.

6. The method of claim 1, wherein generating the CAD model for each concept design further comprises:
identifying interfaces between selected components for each concept design; and
designing custom interfaces for the identified interfaces.

7. The method of claim 1, wherein performing a series of analyses or simulations for the CAD model comprises performing an orbital simulation using an orbital simulation tool.

8. The method of claim 1, wherein performing a series of analyses or simulations for the CAD model comprises performing one or more of finite element analyses (FEA) or finite difference method (FDM) for the CAD model.

9. The method of claim 1, wherein performing a series of analyses or simulations for the CAD model comprises performing a thermal simulation by using a comprehensive, generalized tool for simulating complex thermal or fluid systems.

10. The method of claim 1, further comprising generating a hardware twin that is integrated with the generated digital twin.

11. The method of claim 9, wherein the hardware twin co-evolves with the generated digital twin.

12. A system for automated spacecraft design, the system comprising:
a processor; and
a memory, coupled to the processor, configured to store executable instructions that, when executed by the processor, cause the processor to:
receive mission parameters provided by a client for spacecraft design;
generate one or more concept designs based on the received mission parameters, each concept design including one or more components selected for each subsystem included in a designed spacecraft;
for each concept design, generate a computer aided design (CAD) model including a collection of CADs representing structures of the one or more components selected for each subsystem included in the designed spacecraft;
perform a series of analyses or simulations to evaluate a performance of the CAD model; and
generate a digital twin representing a virtual representation of the designed spacecraft.

13. The system of claim 12, wherein the one or more components are automatically selected for each subsystem included in the designed spacecraft by using a set of codified rules capturing engineering knowledge involved in the spacecraft design.

14. The system of claim 13, wherein the set of codified rules are driven by the mission parameters for the spacecraft design.

15. The system of claim 13, wherein the set of codified rules are driven by a presence of certain components in each design concept.

16. The system of claim 12, wherein, to generate the CAD model for each concept design, the executable instructions further cause the processor to:
import the collection of CADs representing structures of the one or more components into a CAD environment,
automatically design an enclosure for at least one of the one or more components; and
generate a CAD-based model of a spacecraft and combining the CAD models of the one or more components to generate a preliminary spacecraft design for the concept design.

17. The system of claim 12, wherein, to generate the CAD model for each concept design, the executable instructions further cause the processor to:
identify interfaces between selected components for each concept design; and
design custom interfaces for the identified interfaces.

18. The system of claim 12, wherein the series of analyses or simulations for the CAD model include one or more of an orbital simulation using one or more orbital simulation tools including a system took kit (STK), a structural analysis using finite element analyses (FEA) or finite difference method (FDM) for the CAD model, or a thermal simulation by using a comprehensive, generalized tool for simulating complex thermal or fluid systems.

19. The system of claim 12, wherein the executable instructions further cause the processor to generate a hardware twin that is integrated with the generated digital twin.

20. The system of claim 19, wherein the hardware twin co-evolves with the generated digital twin.
